(19) United States
(12) Patent Application Publication
(10) Pub. No.: US 2008/0179614 A1
(43) Pub. Date: Jul. 31, 2008

(54) LIGHT-EMITTING DIODE PACKAGE AND MANUFACTURING METHOD THEREOF

(76) Inventors: Horng-Jou Wang, Taoyuan Hsien (TW); Chi-Hung Kao, Taoyuan Hsien (TW); Huang-Kun Chen, Taoyuan Hsien (TW)

Correspondence Address: BIRCH STEWART KOLASCH & BIRCH, PO BOX 747, FALLS CHURCH, VA, 22040-0747, US

(21) Appl. No.: 11/945,902

(22) Filed: Nov. 27, 2007

(30) Foreign Application Priority Data
Jan. 26, 2007 (TW) 096103005

(51) Int. Cl. H01L 33/00

(52) U.S. Cl. 257/98; 438/27; 257/E33.067

(57) ABSTRACT

A light-emitting diode (LED) package includes a thermal-conducting substrate, a LED element, a package body, and an optical modulation device. The LED element is formed on the thermal-conducting substrate. The package body is formed on the LED element and the thermal-conducting substrate, and the optical modulation device is disposed on a light outputting surface of the package body and has a plurality of stepped protrusions for adjusting a shape of an optical field of the light beam. The optical modulation device and the package body can be two separate components and be connected together, or the optical modulation device and the package body can be integrally formed as a single piece when they are made. In addition, a manufacturing method of the LED package is also disclosed.

### CROSS REFERENCE TO RELATED APPLICATIONS

This Non-provisional application claims priority under 35 U.S.C. §119(a) on patent application Ser. No(s). 096,103,005, filed in Taiwan, Republic of China on Jan. 26, 2007, the entire contents of which are hereby incorporated by reference.

### BACKGROUND OF THE INVENTION

1. Field of Invention

The invention relates to a diode package and a manufacturing method thereof, and in particular to a light-emitting diode (LED) package and a manufacturing method thereof.

2. Related Art

A light-emitting diode (LED) is a light-emitting element made of a semiconductor material. The LED pertains to cold lighting and has advantages of low power consumption, long lifetime, fast response speed and small size. In addition, the LED can be easily fabricated into an extremely small element or LEDs can be easily fabricated into an array device. So, with the recently advancing technology, the application fields of the LED covers an indicator of a computer or home appliance product, a backlight source of a liquid crystal display, a traffic sign or a vehicle indicator, or even a lamp for illumination in the future.

However, the conventional LED still has some problems, such as poor heat dissipation, insufficient light emitting power and poor light emitting efficiency, to be improved. Thus, the current LED still cannot completely replace the lamp.

In addition to the above-mentioned drawbacks, other drawbacks will be described in the following. As shown in FIG. 1A, light outputted from a conventional LED package 1 is mainly gathered around an optical axis OS1. That is, the intensity of light in an area closer to the optical axis OS1 is stronger. Thus, the LED package 1 is adapted to an illumination equipment, such as a flashlight, a table lamp or a traffic sign, with a small angle and concentrated energy. If the LED package 1 is applied to the backlight source of the LCD, a light guide plate and a diffuser plate have to be correspondingly used in order to provide a uniform backlight source for a LCD panel.

In addition, as shown in FIG. 1B, another conventional LED package 2 utilizes a lens 21 to cover a LED element 22 in order to provide a uniform and wide light emitting area. The lens 21 has a concave portion 211 around an optical axis OS2, and the concave portion 211 effectively refracts the light generated by the LED element 22 so that the light travels away from the optical axis OS2 and is then outputted from the lens 21, and the light emitting area is thus enlarged.

As mentioned hereinabove, the light emitting area of the LED is enlarged. However, the shape of the optical field caused by the typical LED is a circular shape, as shown in FIG. 1C. So, when several LEDs 3 are arranged together and emit the light simultaneously, the shapes of the optical fields thereof have an overlapped area A01 being generated. Consequently, the phenomenon of the nonuniform light intensity still cannot be improved.

Therefore, it is an important subject to provide a LED package capable of adjusting the shape of the optical field and the intensity distribution of the optical field, and a manufacturing method thereof.

### SUMMARY OF THE INVENTION

In view of the foregoing, the invention is to provide a LED package capable of generating the uniform optical intensity distribution, and a manufacturing method thereof.

To achieve the above, the invention discloses a light-emitting diode (LED) package, which includes a thermal-conducting substrate, a LED element and a package body. The LED element is formed on the thermal-conducting substrate and generates a light beam. The package body is formed on the LED element and the thermal-conducting substrate. A light outputting surface of the package body has a plurality of stepped protrusions for adjusting a shape of an optical field of the light beam.

In addition, the invention discloses a light-emitting diode (LED) package, which includes a thermal-conducting substrate, a LED element, a package body and an optical modulation device. The LED element is formed on the thermal-conducting substrate and generates a light beam. The package body is formed on the LED element and the thermal-conducting substrate. The optical modulation device is disposed on a light outputting surface of the package body and has a plurality of stepped protrusions.

To achieve the above, the invention also discloses a manufacturing method of a light-emitting diode (LED) package. The method includes the steps of: forming a LED element on a thermal-conducting substrate; and forming a package body on the LED element and the thermal-conducting substrate. Herein, a light outputting surface of the package body has a plurality of stepped protrusions.

In addition, the invention also discloses a manufacturing method of a light-emitting diode (LED) package, including the steps of: forming a LED element on a thermal-conducting substrate, the LED element generating a light beam, forming a package body on the LED element and the thermal-conducting substrate, forming an optical modulation device having a plurality of stepped protrusions, and disposing the optical modulation device on the package body to adjust a shape of an optical field of the light beam.

In summary, the stepped protrusions, which can be the binary optical protrusions, are formed on the light outputting surface of the package body in the LED package and the manufacturing method thereof according to the invention. So, the stepped protrusions can adjust the shape of the optical field of the light outputted from the LED to be the triangular, tetragonal or any other shape. In addition, the design of each stepped protrusion can be adjusted so that the object of making the light be uniformly distributed can be achieved.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic illustration showing a conventional LED package;

FIG. 1B is a schematic illustration showing another conventional LED package;

FIG. 1C is a schematic illustration showing a shape of an optical field generated by the conventional LED;

FIG. 2 is a schematic illustration showing a LED package according to a first embodiment of the present invention;

FIG. 3 is a flow chart showing a manufacturing method of the LED package according to the first embodiment of the present invention;

FIGS. 4A to 4C are schematic illustrations showing detailed steps in the step S02 of FIG. 3;

FIGS. 4D to 4F are schematically cross-sectional views showing various stepped protrusions in the dashed-line circular portion of FIG. 4C;

FIGS. 5A to 5D are other schematic illustrations showing detailed steps in the step S02 of FIG. 3;

FIG. 6 is a schematic illustration showing a LED package according to a second embodiment of the present invention;

FIGS. 7A to 7D are schematic illustrations showing variations of the LED package according to the second embodiment of the present invention;

FIG. 8 is a flow chart showing a manufacturing method of the LED package according to the second embodiment of the present invention;

FIGS. 9A to 9C are schematic illustrations showing a manufacturing method of the LED package according to the flow of FIG. 8;

FIGS. 10A and 10B are schematic illustrations showing shapes of optical fields caused by the LED according to the embodiment of the present invention;

FIG. 11 is another schematic illustration showing the LED package according to the present invention; and

FIGS. 12A and 12B are other schematic illustrations showing the LED package according to the present invention.

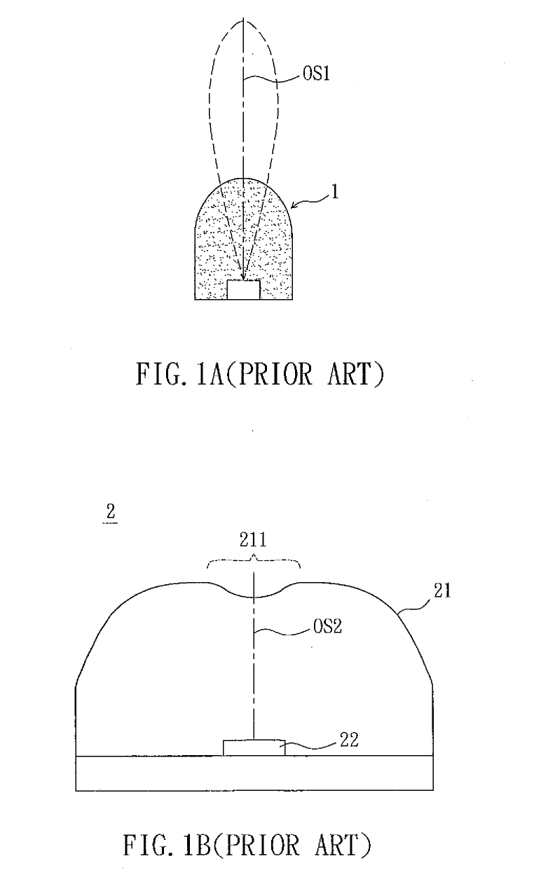

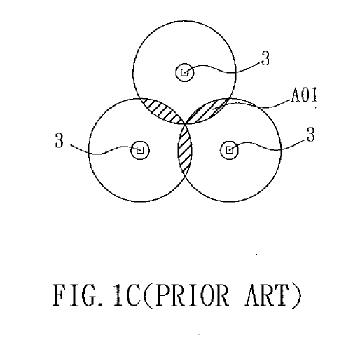

### DETAILED DESCRIPTION OF THE INVENTION

The present invention will be apparent from the following detailed description, which proceeds with reference to the accompanying drawings, wherein the same references relate to the same elements.

### First Embodiment

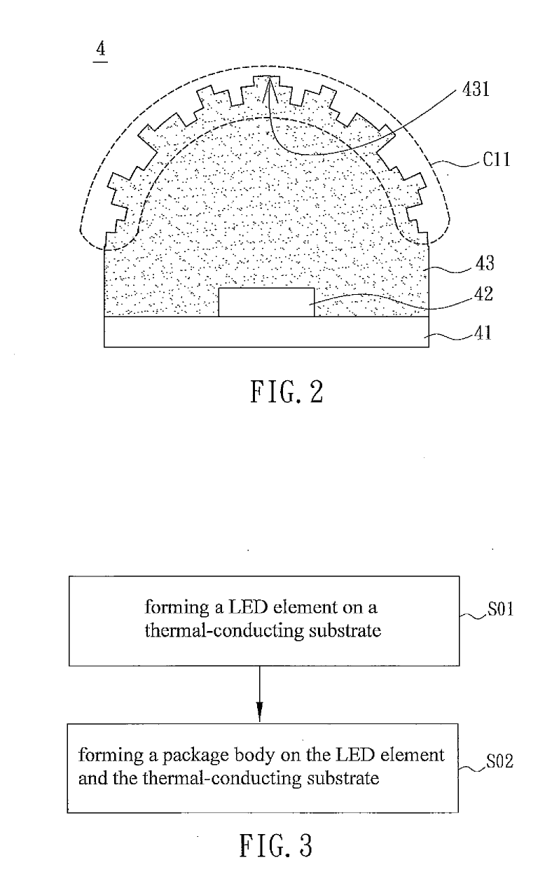

Referring to FIG. 2, a LED package 4 according to the first embodiment of the present invention includes a thermal-conducting substrate 41, a LED element 42 and a package body 43.

The LED element 42 is formed on the thermal-conducting substrate 41 and generates a light beam. In this embodiment, the material of the thermal-conducting substrate 41 can be silicon, gallium arsenide, gallium phosphide, silicon carbide, boron nitride, aluminum, aluminum nitride, copper or combinations thereof. The material of the package body 43 can be light-permeable resin, a polymeric material, optical glass or combinations thereof.

The package body 43 is formed on the thermal-conducting substrate 41 and the LED element 42, and a light outputting surface 431 of the package body 43 has a plurality of stepped protrusions C11. The light beam generated by the LED element 42 travels to the light outputting surface 431 and is then outputted from the light outputting surface 431.

The stepped protrusions C11 of the package body 43 can be arranged in an axially symmetrical manner, a non-axially symmetrical manner or an irregular manner according to different shapes of optical fields and different intensities of the optical fields. In this example, the stepped protrusions C11 are arranged in the irregular manner In addition, each of the stepped protrusions C11 is a binary optical protrusion. In other words, the stepped protrusions C11 have 2^{N} steps, wherein N is a positive integer, such as 1, 2, 3, etc. Each of the stepped protrusions C11 has a flat surface.

Referring to FIG. 3 in conjunction with the descriptions mentioned hereinabove, a manufacturing method of the LED package 4 according to the first embodiment of the present invention includes steps S01 and S02. In the step S01, a LED element 42 is formed on a thermal-conducting substrate 41. In the step S02, a package body 43 is formed on the LED element 42 and the thermal-conducting substrate 41, wherein a light outputting surface 431 of the package body 43 has a plurality of stepped protrusions C11.

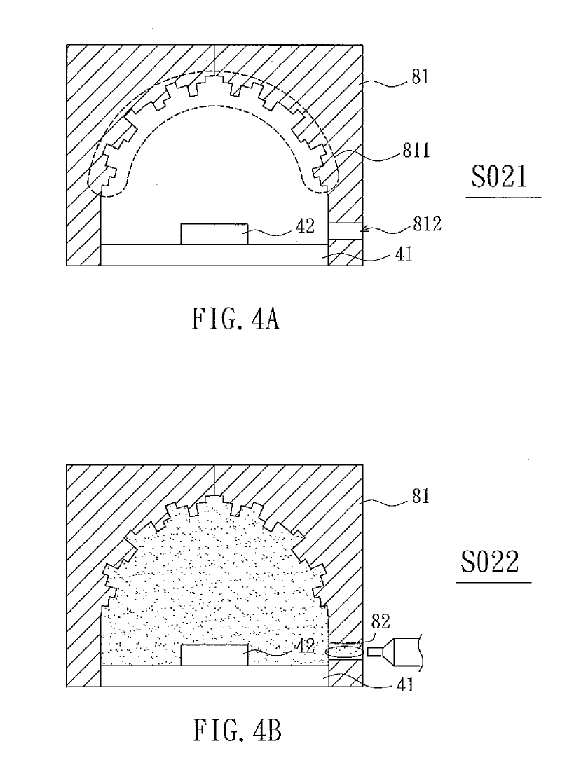

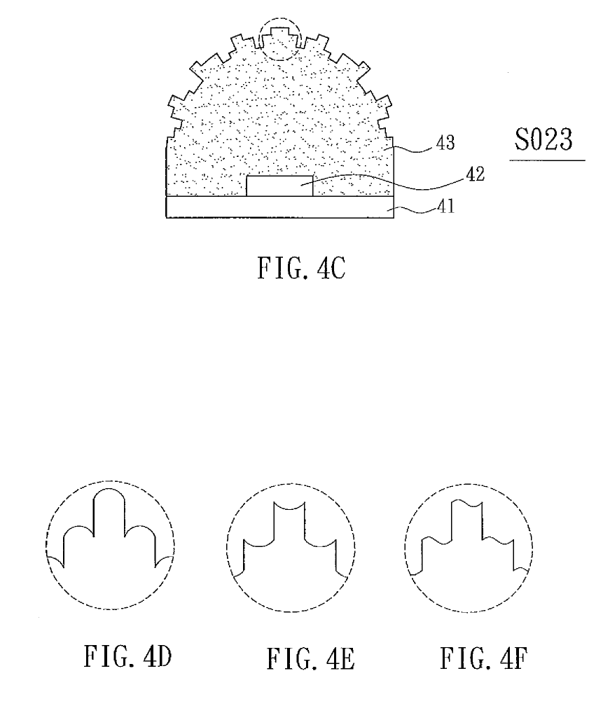

As mentioned hereinabove, the package body 43 is formed by way of injection in conjunction with a mold. In detail, as shown in FIGS. 4A to 4C, the step of forming the package body 43 includes steps S021 to S023.

As shown in FIG. 4A, a mold 81 is disposed on the thermal-conducting substrate 41 and the LED element 42 in the step S021, wherein the mold 81 has an injection hole 812 and a reverse pattern 811 to the stepped protrusions C11. As shown in FIG. 4B, a package material 82 is injected into the mold 81 through the injection hole 812 in the step S022 so that the mold 81 is fulled with the package material 82. As shown in FIG. 4C, the mold 81 is removed after the package material 82 is molded in the step S023 so that the package body 43 having the stepped protrusions C11 is formed. It is to be noted that the package material 82 can be heated or illuminated by ultra-violet rays to solidify and thus to form the package body 43 after the package material 82 is injected into the mold 81.

As shown in FIGS. 2 and 4C, it is to be noted that each of the stepped protrusions C11 on the package body 43 is a binary optical protrusion having a flat surface in this non-limitative example. For example, each of the stepped protrusions C11 can also be a protrusion having a curved surface, and having a convex cross-section (see FIG. 4D), a concave cross-section (see FIG. 4E), a wavy cross-section (see FIG. 4F) or any other shape. Also, for the sake of clear illustration, FIGS. 4D to 4F only show the schematically cross-sectional views of various stepped protrusions in the dashed-line circular portion of FIG. 4C. However, all types of the stepped protrusions C11 on the package body 43 can be applied.

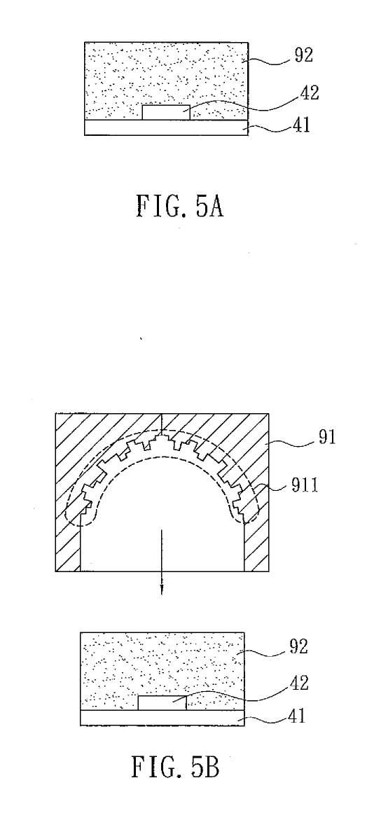

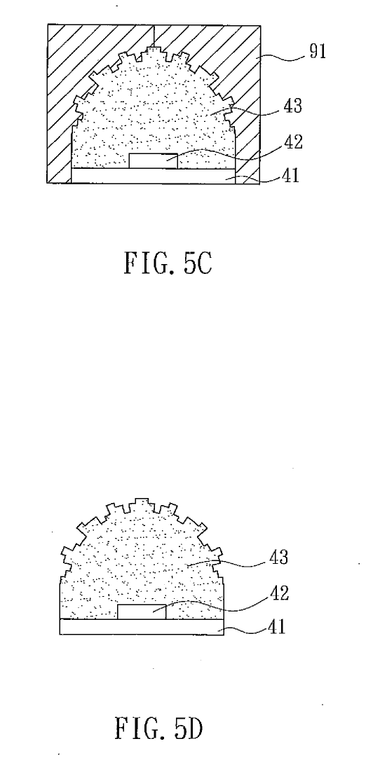

In addition, as shown in FIGS. 5A to 5D, the package body 43 can also be formed by way of pressing in conjunction with a mold 91. In detail, the step of forming the package body 43 includes the following steps.

As shown in FIG. 5A, a package material 92 covers the thermal-conducting substrate 41 and the LED element 42. As shown in FIGS. 5B and 5C, the mold 91 having a reverse pattern 911 to the stepped protrusions C11 is pressed onto the package material 92 so that the reverse pattern 911 to the stepped protrusions C11 is transposed onto the package material 92. As shown in FIG. 5D, the mold 91 is removed to form the package body 43 having the stepped protrusions C11. It is to be noted that after the mold 91 is pressed onto the package material 92, the package material 92 can be heated or illuminated by the ultra-violet rays to solidify and thus to form the package body 43.

### Second Embodiment

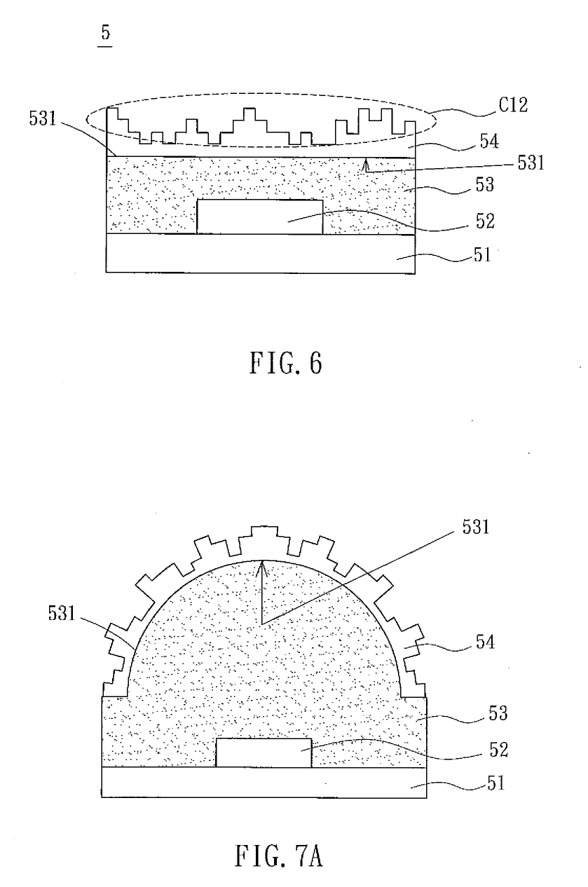

Referring to FIG. 6, a LED package 5 according to the second embodiment of the present invention includes a thermal-conducting substrate 51, a LED element 52, a package body 53 and an optical modulation device 54.

The LED element 52 is formed on the thermal-conducting substrate 51 and generates a light beam. The package body 53 is formed on the thermal-conducting substrate 51 and the LED element 52. The optical modulation device 54 is disposed on a light outputting surface 531 of the package body 53 and has a plurality of stepped protrusions C12. In this embodiment, the material of the thermal-conducting substrate 51 can be silicon, gallium arsenide, gallium phosphide, silicon carbide, boron nitride, aluminum, aluminum nitride, copper or combinations thereof. The material of the package body 53 can be light-permeable resin, a polymeric material, optical glass or combinations thereof.

In addition, the functions of these stepped protrusions C12 according to this embodiment are the same as those of the stepped protrusions C11 according to the first embodiment and have been mentioned hereinabove, so detailed descriptions thereof will be omitted.

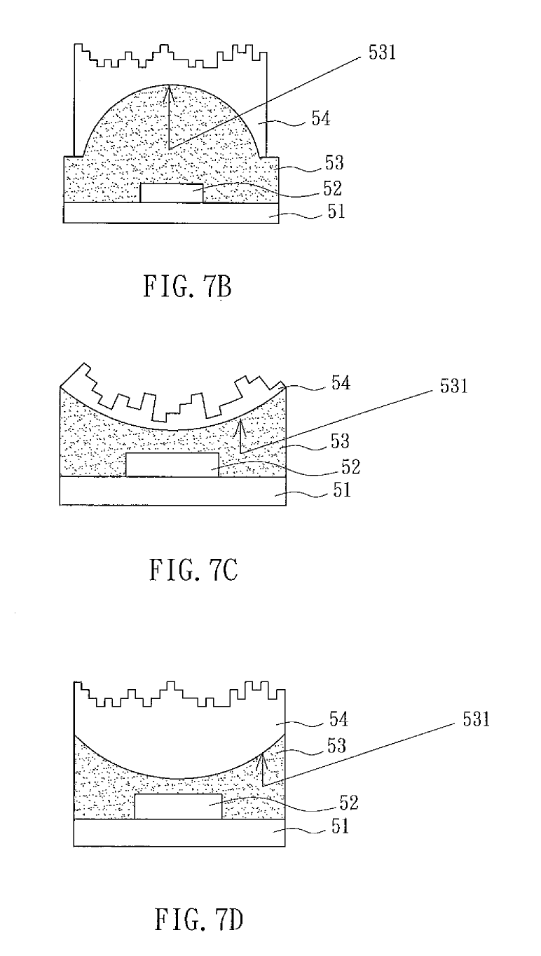

It is to be specified that the light outputting surface 531 of the package body 53 can be a curved surface and the light outputting surface 531 can be a curved surface (not shown) having a refractive optical device, as shown in FIG. 7A. The curved surface of the refractive optical device can function to reduce the color difference and the thermal difference. In addition, the light outputting surface 531 can be a convex curved surface (see FIGS. 7A and 7B), a concave curved surface (see FIGS. 7C and 7D) or any other combined curved surface according to different optical systems.

Furthermore, the optical modulation device 54 disposed on the package body 53 can also have a convex curved surface (see FIG. 7A), a concave curved surface (see FIG. 7C), a flush curved surface (see FIGS. 7B and 7D) or any other combined curved surface according to different shapes of the optical fields and different intensities of the optical fields. However, the light outputting surface 531 of the package body 53 and the optical modulation device 54 can have various shapes, and can arbitrarily match with each other according to different design requirements without being limited to the above-mentioned aspects.

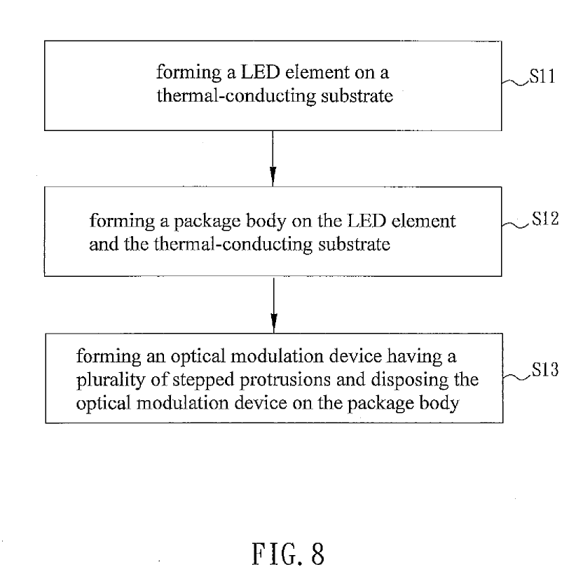

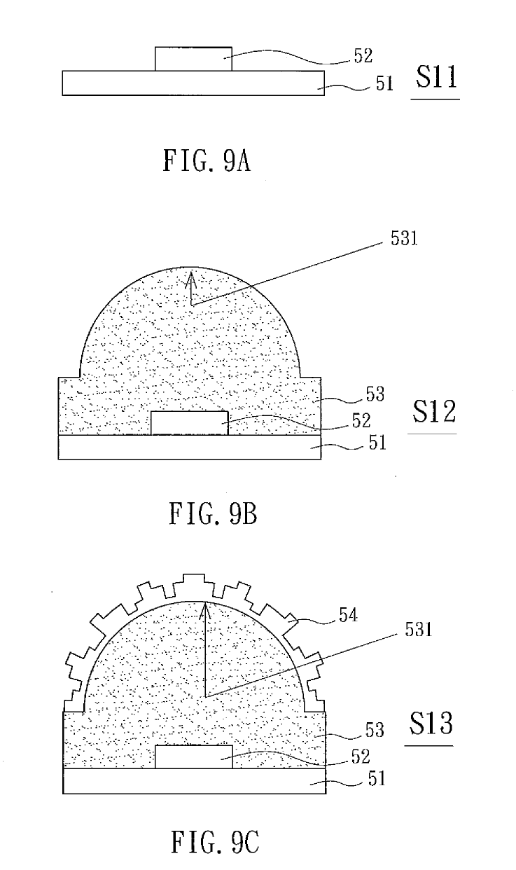

A manufacturing method of the LED package 5 according to the second embodiment of the present invention will be described with reference to FIG. 8 in conjunction with FIGS. 9A to 9C. The manufacturing method of the LED package 5 includes steps S11 to S13.

As shown in FIG. 9A, a LED element 52 is formed on a thermal-conducting substrate 51 in the step S11. As shown in FIG. 9B, a package body 53 is formed on the LED element 52 and the thermal-conducting substrate 51 in the step S12, wherein the package body 53 has a light outputting surface 531. In the step S13, an optical modulation device 54 having a plurality of stepped protrusions C12 is formed and disposed on the package body 53. In this embodiment, the optical modulation device 54 can be a light-permeable adhesive layer (not shown) adhered to the package body 53. It is noted that the optical modulation device and the package body in the second embodiment are two separate components and are connected together in sequential steps, but the optical modulation device and the package body in the first embodiment are integrally formed as a single piece when they are made.

As mentioned hereinabove, the step of forming the optical modulation device 54 can further include steps S131 to S133.

In the step S131, a reverse pattern to these stepped protrusions C12 is transposed onto a light-permeable material. In the step S132, the light-permeable material is heated or illuminated by ultra-violet rays to solidify and thus to form the optical modulation device 54. In the step S133, the mold is removed to form the optical modulation device 54 having the stepped protrusions C12.

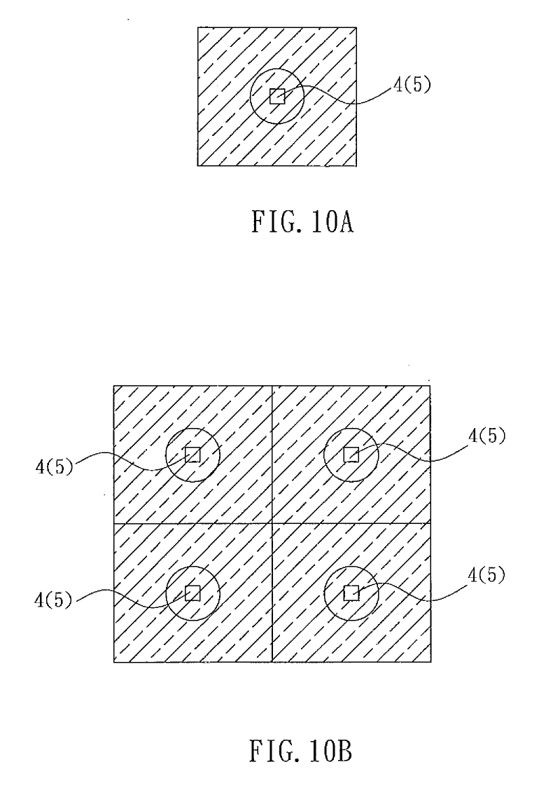

As mentioned hereinabove, the light beam of the LED package 4/5 of the first/second embodiment passes through the stepped protrusions to form the shape of the optical field shown in FIG. 10A. Adjusting the stepped protrusions C11/C12 of the embodiment can arbitrarily adjust the distribution of the intensity of the optical field of the LED package 4/5. The shape of the optical field is a tetragonal shape in this example. Of course, the shape of the optical field can include, without limitation to, a polygonal shape, such as a triangular shape, a hexagonal shape or an octagonal shape, according to the designs of the stepped protrusions C11/C12.

Next, as shown in FIG. 10B, when the LED packages 4 or 5 are arranged in parallel or in an array, the shapes of the optical fields can be arranged densely without overlap. In addition, the intensity of the optical field has the uniform distribution so that a uniform plane light source can be obtained.

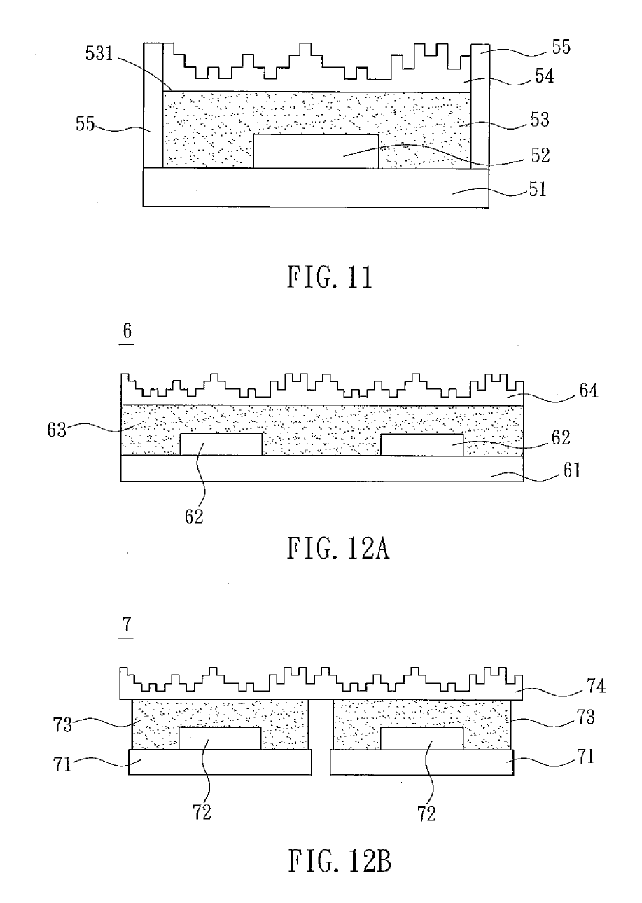

In addition to the above-mentioned aspects of the LED package, the LED package 5 according to the second embodiment of this invention can further include a support frame 55 connected to and between the optical modulation device 54 and the thermal-conducting substrate 51 to support the optical modulation device 54, as shown in FIG. 11.

In addition, as shown in FIG. 12A, several LED elements 62 can also be disposed on a thermal-conducting substrate 61 in this embodiment, a package body 63 is formed on the thermal-conducting substrate 61 and the LED elements 62, and an optical modulation device 64 is disposed on the package body 63. In addition, as shown in FIG. 12B, LED elements 72 can be respectively disposed on thermal-conducting substrates 71 and package bodies 73 are respectively formed on the LED elements 72 and the thermal-conducting substrates 71, and then an optical modulation device 74 is disposed on the package bodies 73. In other words, multiple LED elements can share the same optical modulation device to be flexibly adapted to various designs.

In summary, the stepped protrusions, which can be the binary optical protrusions, are formed on the light outputting surface of the package body in the LED package and the manufacturing method thereof according to the present invention. So, the stepped protrusions can adjust the shape of the optical field of the light outputted from the LED to be the triangular, tetragonal or any other shape. In addition, the design of each stepped protrusion can be adjusted so that the intensity of the optical field of the light beam generated by the LED element can be adjusted and the object of making the light be uniformly distributed can be achieved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) package, comprising:
a thermal-conducting substrate;
a LED element, which is formed on the thermal-conducting substrate and generates a light beam;
a package body formed on the LED element and the thermal-conducting substrate; and
an optical modulation device, which is disposed on a light outputting surface of the package body and has a plurality of stepped protrusions for adjusting a shape of an optical field of the light beam.

2. The LED package according to claim 1, wherein each of the stepped protrusions is a binary optical stepped protrusion.

3. The LED package according to claim 2, wherein the stepped protrusions has 2^{N} steps, and N is a positive integer.

4. The LED package according to claim 2, wherein each of the stepped protrusions has a flat surface or a curved surface.

5. The LED package according to claim 1, wherein the stepped protrusions are arranged in an axially symmetrical manner, a non-axially symmetrical manner or an irregular manner.

6. The LED package according to claim 1, wherein the shape of the optical field is a triangular shape, a tetragonal shape or a polygonal shape.

7. The LED package according to claim 1, wherein the thermal-conducting substrate comprises silicon, gallium arsenide, gallium phosphide, silicon carbide, boron nitride, aluminum, aluminum nitride, copper or combinations thereof.

8. The LED package according to claim 1, wherein the package body comprises light-permeable resin, a polymeric material, optical glass or combinations thereof.

9. The LED package according to claim 1, wherein the light outputting surface of the package body comprises a curved surface.

10. The LED package according to claim 9, wherein the curved surface is a convex curved surface, a concave curved surface or an irregular curved surface.

11. The LED package according to claim 1, wherein the optical modulation device has a convex, concave, flush or irregular curved surface disposed on the package body.

12. The LED package according to claim 1, further comprising:
a support frame connected to and between the optical modulation device and the thermal-conducting substrate for supporting the optical modulation device.

13. The LED package according to claim 1, wherein the optical modulation device and the package body are integrally formed as a single piece.

14. A manufacturing method of a light-emitting diode (LED) package, comprising steps of:
forming a LED element on a thermal-conducting substrate; and
forming a package body on the LED element and the thermal-conducting substrate, wherein a light outputting surface of the package body has an optical modulation device with a plurality of stepped protrusions for adjusting a shape of an optical field of the light beam.

15. The manufacturing method according to claim 14, wherein the step of forming the package body comprises:
placing a mold, which has an injection hole and a reverse pattern to the stepped protrusions, on the thermal-conducting substrate and the LED element;
injecting a package material into the mold through the injection hole; and
removing the mold to form the package body having the stepped protrusions.

16. The manufacturing method according to claim 15, wherein after the step of injecting the package material into the mold, the method further comprises a step of:
solidifying the package material to form the package body by being heated or illuminated by ultra-violet rays.

17. The manufacturing method according to claim 14, wherein the step of forming the package body comprises:
using a package material to cover over the thermal-conducting substrate and the LED element;
pressing a mold having a reverse pattern to the stepped protrusions onto the package material to transpose the reverse pattern onto the package material; and
removing the mold to form the package body having the stepped protrusions.

18. The manufacturing method according to claim 17, wherein after the step of:
pressing the mold onto the package material, the method further comprises a step of solidifying the package material to form the package body.

19. A manufacturing method of a light-emitting diode (LED) package, comprising steps of:
forming a LED element on a thermal-conducting substrate, the LED element generating a light beam;
forming a package body on the LED element and the thermal-conducting substrate; and
forming an optical modulation device having a plurality of stepped protrusions, and disposing the optical modulation device on the package body for adjusting a shape of an optical field of the light beam.

20. The manufacturing method according to claim 19, wherein the optical modulation device is adhered to the package body by a light-permeable adhesive layer.
